(19) United States
(12) Patent Application Publication
(10) Pub. No.: US 2009/0261838 A1
(43) Pub. Date: Oct. 22, 2009

(54) Battery monitor for marine applications

(75) Inventor: Daniel Shull, Newman Lake, WA (US)

Correspondence Address: WELLS ST. JOHN P.S., 601 W. FIRST AVENUE, SUITE 1300, SPOKANE, WA, 99201, US

(73) Assignee: Heater Craft Marine Products

(21) Appl. No.: 12/083,000

(22) Filed: Apr. 16, 2008

(51) Int. Cl. G01R 19/165

(52) U.S. Cl. 324/433

(57) ABSTRACT

A battery monitor for marine applications which includes a first voltage comparator circuit which compares the voltage input of a marine battery to a first predetermined reference voltage; an audible alarm which operates when the voltage comparator circuit determines that the voltage input of the marine battery is below that of the first predetermined reference voltage, and wherein the battery monitor draws less than 100 milliamps of current on a continuous basis while monitoring the voltage input of the marine battery.

### TECHNICAL FIELD

The present invention relates to a battery monitor for marine applications, and more specifically, to an assembly which monitors the electrical charge state of one or more batteries and then provides a visual and/or audio alarm to alert an operator of a marine craft that the electrical charge of a given battery on the watercraft requires immediate attention.

### BACKGROUND OF THE INVENTION

The beneficial effects of employing battery monitors for various industrial applications have long been known. For example, many computer accessory manufacturers have produced battery monitoring alarms which have been employed, heretofore, to determine the electrical charge state of batteries (which may be individual valve-regulated or wet cell type), and which are in series and/or parallel, and which are further used as an uninterruptible power supply to maintain critical loads in the event of loss of power. Such alarm systems have been used, heretofore, to alert a business owner about a potential failure in their backup power supply. Such systems have often included features such as a 1000 event alarm history which enables the owner to track battery discharges, recharges, temperature conditions and low/high voltage batteries. By monitoring these conditions, an owner can assure himself that an uninterruptible power supply will be able to maintain a critical load during a power disturbance.

A battery monitor which finds particular usefulness in a marine application is the subject matter of the present application.

### SUMMARY OF THE INVENTION

Therefore, a first aspect of the present invention relates to a battery monitor for marine applications which includes a first voltage comparator circuit which compares a voltage input of a marine battery to a first predetermined reference voltage; and an audible alarm which operates when the voltage comparator circuit determines that the voltage input of the marine battery is below that of the first predetermined reference voltage, and wherein the battery monitor draws less than 100 milliamps of current on a continuous basis while monitoring the voltage input of the marine battery.

Still another aspect of the present invention relates to a battery monitor for marine applications which includes a voltage input which receives a voltage from a marine battery; a first comparator circuit which compares the voltage input of the marine battery to a predetermined reference undervoltage setting; a second comparator circuit which compares the voltage input of the marine battery to a predetermined reference overvoltage setting; an audible alarm which operates when either the first comparator circuit determines that the voltage input of the marine battery is below the predetermined reference undervoltage setting, or when the second comparator circuit determines that the voltage input of the marine battery is above the predetermined reference overvoltage setting; and a numerical display which displays the value of the voltage input of the marine battery.

Still further, the present invention relates to a battery monitor for marine applications which includes a first voltage input which receives a voltage from a first marine battery; a second voltage input which receives a voltage from a second marine battery; a first comparator circuit which compares the first and second voltage inputs to a predetermined reference undervoltage setting; a second comparator circuit which compares the first and second voltage inputs to a predetermined reference overvoltage setting; an audible alarm which operates when either the first comparator circuit determines that either the first or second voltage input is below the predetermined reference undervoltage setting, or when the second comparator circuit determines that either the first or second voltage input is above the predetermined reference overvoltage setting; and a battery display selector switch which selects either the first or second voltage input value to be displayed upon a numerical display.

These and other aspects of the present invention will be described in greater detail hereinafter.

### BRIEF DESCRIPTION OF THE DRAWINGS

Preferred embodiments of the invention are described below with reference to the following accompanying drawings.

FIG. 1 is a perspective, environmental view of a battery monitor for marine applications shown on a watercraft of conventional design, with at least one surface removed to show the structure thereunder.

FIG. 1A is a greatly enlarged, side elevation view of two marine batteries which are mounted on the watercraft as seen in FIG. 1, and which are shown in a typical electrical configuration.

FIG. 2 is a perspective, front elevation view of the battery monitor for marine applications of the subject invention.

FIG. 3 is an electrical schematic drawing of the battery monitor for marine applications of the subject invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

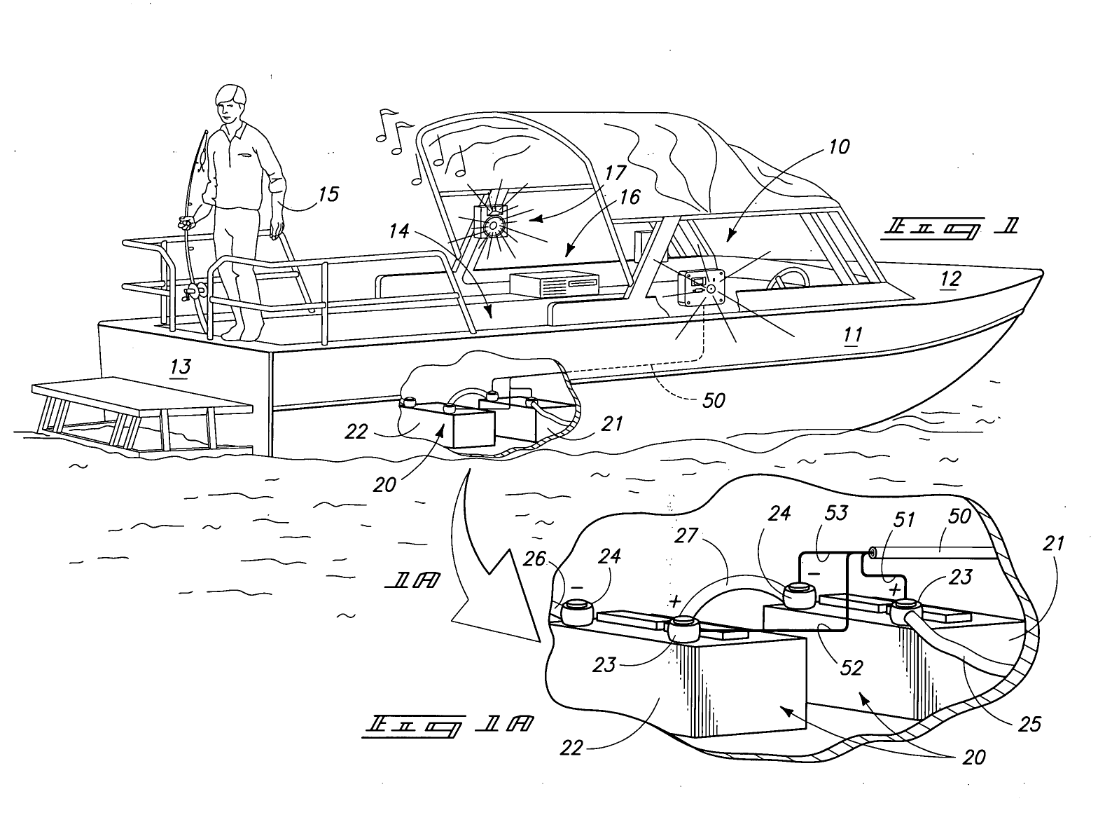

For illustrative convenience, the battery monitor for marine applications 10 of the present invention is shown installed in a conventional environment as seen in FIG. 1. In that view, it will be understood that a watercraft 11 includes a bow 12, stern 13, and cockpit region 14 which permits an operator 15 such as a fisherman (as shown) to enjoy the surrounding water while the boat is operational, or further, while it is non-operational or just drifting. As seen in FIG. 1, the watercraft 11 typically includes various types of electrical appliances which draws electrical power from the watercraft while it is operational, or just drifting. In FIG. 1, it will be seen that a stereo, radio or compact disc player 16 is provided and which is mounted in the cockpit 14 and which is electrically coupled with a speaker 17 that is supplying music to the fisherman 15 as he enjoys the use of the watercraft 11. As should be understood, and particularly when the watercraft is not operational and merely drifting, the electrical appliance such as the stereo, radio/compact disc player 16 draws electrical power from the marine batteries which are generally indicated by the numeral 20. In most marine applications, several batteries 20 may be provided for the operation of the watercraft 11. In many instances, the watercraft will be supplied with two batteries. A first or main marine battery 21 is provided for the purpose of starting the internal combustion engine (not shown) and that drives the watercraft 11. Further, a second or auxiliary marine battery 22 (house battery) is provided so as to run auxiliary electrical appliances on the watercraft when the watercraft is not operational. The first and second marine batteries 21 and 22 may be electrically connected together in any number of different ways including serial, or parallel arrangements or they may be completely separated one from the other so that if one battery was to become electrically discharged, it would not cause both batteries to become disabled. In some marine applications, these first and second marine batteries may be electrically coupled to a battery switch (not shown) and which allows the operator 15 to select the battery from which he wishes to draw electrical power. For example, the battery switch may permit the user of the watercraft 11 to draw power primarily from the first marine battery 21; second marine battery 22 or both first and second marine batteries 21 and 22, respectively, depending upon the state of charge of the respective batteries. Each of the marine batteries 21 and 22 have a positive terminal 23 and a negative terminal 24. Still further, in the arrangement as seen in FIG. 1A, the first and second batteries 21 and 22 are serially electrically coupled together. In this arrangement, a first battery cable 25, and a second battery cable 26 provides electrical power to the watercraft 12, or to an electrical switch as earlier described. Still further, a third battery cable 27 is provided and which extends between the negative terminal 24 of the first marine battery to the positive terminal 23 of the second or auxiliary marine battery 22.

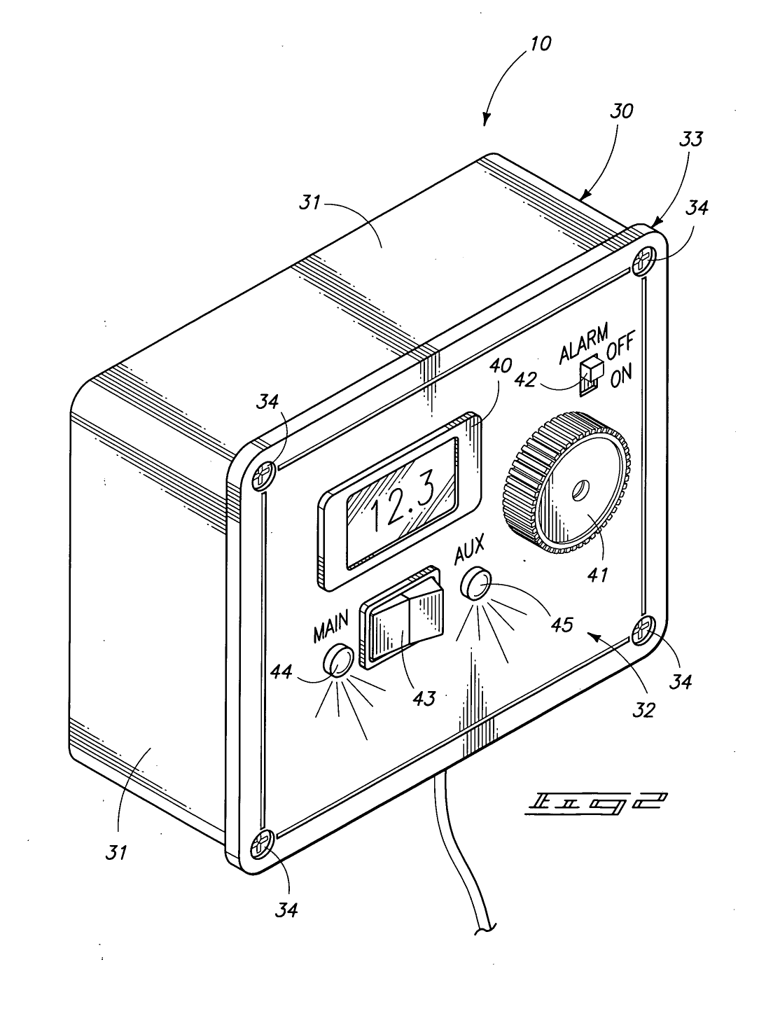

Referring now to FIG. 2, the battery monitor for marine applications 10 of the present invention is shown in a perspective, front elevation view. As seen therein, the battery monitor 10 includes a waterproof housing, which is generally indicated by the numeral 30, and which is comprised of a plurality of sidewalls 31. The plurality of sidewalls define an internal cavity (not shown) which encloses the electrical circuitry comprising the battery monitor as will be described in greater detail hereinafter. The battery monitor 10 has a face plate, which is generally indicated by the numeral 32, and which is sealably mounted to the waterproof housing 30. The face plate has a peripheral edge 33. A plurality of apertures 34 are located adjacent to the peripheral edge and allow fasteners of conventional design to extend therethrough and engage a supporting surface of the watercraft 11 so as to mount the battery monitor 10 in a predetermined location preferably within the cockpit 14 or other convenient location on the watercraft 11. As seen in FIG. 2, the battery monitor 10 includes an alpha-numeric electrical display which is generally indicated by the numeral 40, and which is operable to display the current voltage of the marine battery 20 which is being monitored. Still further, the battery monitor 10 includes an audio alarm 41 which, when energized by the battery monitor, is operable to provide a sufficiently loud audio alarm so that a user 15 of a watercraft 11, as seen in FIG. 1, may be alerted to an unsatisfactory electrical charge state of the battery being monitored. The audio alarm is sufficiently loud enough that the operator 15 may be alerted to the unsatisfactory electrical charge state of a marine battery 20, even while the watercraft 11 is in operation. This might be the case where the motor of the watercraft 11 is charging the marine batteries 20 on the watercraft and an electrical malfunction has occurred such that the generator or alternator of the watercraft 11 is overcharging one or both of the batteries thereby allowing a dangerous and sometimes explosive situation to develop. Moreover, the audio alarm is loud enough so that it may gain an operator's 15 attention, even when the operator is at some distance from the watercraft 11 as may be the situation where an electrical appliance is operational on a watercraft when it is tied to a dock, or anchored near shore and where the operator of the watercraft has disembarked, or gone ashore, and is located at a distance from the watercraft 11. In the arrangement as seen in FIG. 2, the battery monitor 10 includes an audio alarm electrical switch 42 which allows a user 15 to enable or disable the audio alarm 14. Still further, the battery monitor 10 includes a three position battery selection switch 43 which allows a user 15 to select the specific marine battery 20 that they wish to monitor (21 or 22). When the switch is positioned in an intermediate position, the battery monitor is turned off and does not display any voltage information on the display 40. As seen in this arrangement, the battery monitor 10 allows an operator 15 to monitor both the main or first marine battery 21 and a second or auxiliary marine battery 22. By merely depressing the two position battery selection switch 43, the charge state of specific marine battery 20 may be selected. As seen in the drawing, the operator 15 selected the main or first marine battery 21 to be monitored. As illustrated, the alpha-numeric electric display 41 shows that the first marine battery has a voltage of about 12.3 volts. Still further, the battery monitor 10 of the present invention includes two electrical charge status lights. These are identified as a first marine battery charge status light 44, and a second marine battery charge status light 45. When an appropriate marine battery 20 has been selected by means of the battery selection switch 43, the respective battery charge status light will then provide an appropriate visual signal to alert an operator 15 of the watercraft 11 regarding the battery charge status of the marine battery 20 being monitored. For example, in the arrangement as seen in FIG. 2, when the first marine battery 21 is selected, and the electrical charge of this battery is 12.3 volts, the charge status light 44 would be illuminated to provide a green color. On the other hand, if the first marine battery 21 had been discharged to a predetermined voltage below 12.3 Volts, as will be discussed in greater detail hereinafter, the battery charge status light 44 would be illuminated red. In this manner, the operator 15 of watercraft 11 can be alerted to the status of the marine batteries 20 by a quick visual check of the face plate 32 of the battery monitor 10 especially when the audio alarm electrical switch 42 has been disabled. As best understood by a study of FIGS. 1 and 1A, the battery monitor 10 is electrically coupled to the respective first and second marine batteries 21 and 22, respectively by means of an electrical conduit which is generally indicated by the numeral 50. The electrical conduit includes first, second and third electrical leads 51, 52 and 53, respectively. As seen in FIG. 1A, the first and second electrical leads 51 and 52 are individually electrically coupled to the positive terminals 23 of the respective first and second marine batteries 21 and 22, respectively. Further, the third electrical lead 53 is electrically coupled to one of the negative terminals 24 of one of the marine batteries 20.

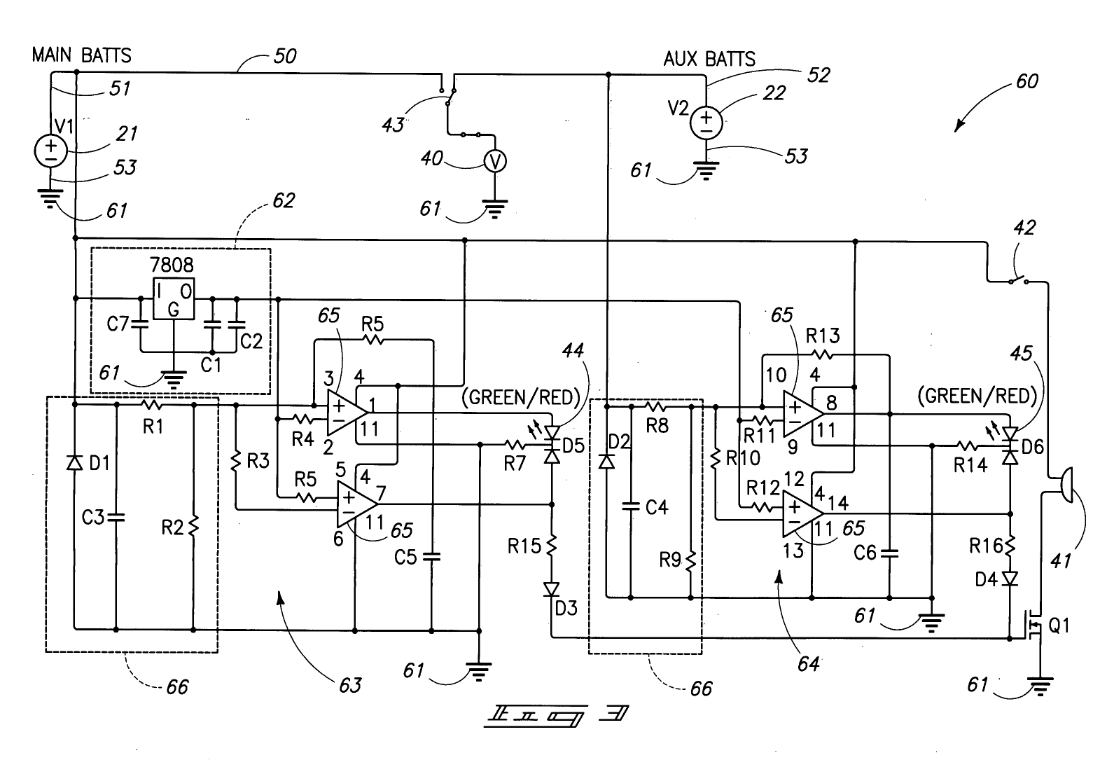

Referring now more specifically to FIG. 3, which depicts an exemplary schematic diagram of the electrical circuit which implements the features of the present invention, an electrical circuit 60 is provided and which includes the following features. A first voltage input V1, as shown on FIG. 3, is supplied from the first or main marine battery 21 and represents the voltage level of that battery or group of batteries. Likewise, a second voltage input V2 is supplied from the second or auxiliary marine battery 22 and represents the voltage level of that battery or group of batteries. A battery selector switch 43 selects a connection with either the first voltage V1 or the second voltage V2 to a voltmeter 40 to display the voltage level of the selected battery or group of batteries. This switch is a three position switch as earlier disclosed. When placed in the intermediate position, no voltages are displayed on the electrical display 41. A common ground 61 is provided for the electrical circuit 60 and is electrically tied to the negative terminals 24 of the first and second batteries 21 and 22.

In FIG. 3, the reference numerals have been placed near the element being described. The applicant has eliminated lead lines so as to ensure an easy understanding of the drawing. The electrical circuit 60 generally comprises a first voltage comparator circuit 63 and a second voltage comparator circuit 64, which shall be discussed in detail below. A reference voltage is supplied to each comparator circuit 63 and 64 from the first or main battery 21 via a voltage regulator circuit, generally indicated by the numeral 62. The voltage regulator circuit 62 comprises a 7808 three-pin voltage regulator, housed in a single integrated circuit, and which is commonly available from any of a number of integrated circuit manufacturers. The first battery source 21 is connected to the IN terminal of the 7808 voltage regulator (designated I), shunted by a capacitor C7, generally sized at 0.01 microfarads. The OUT terminal of the 7808 (designated O) is shunted by two capacitors, C1 and C2, generally sized at 220 microfarads and 0.01 microfarads, respectively. The ground terminal (designated G) of the 7808 voltage regulator is connected to the common ground 61.

Referring still to FIG. 3, the first and second voltage comparator circuits 63 and 64 each comprise two operational amplifiers, which are provided by a LM224 quad operational amplifier, generally indicated by the numeral 65. The operational amplifier which is commercially designated as LM224 is a single integrated circuit containing four operational amplifiers. The LM224 is commonly available from any of a number of integrated circuit manufacturers, including Texas Instruments and Fairchild Electronics. Power is supplied to the operational amplifier 65 by a connection made from the first battery source 21 to the input power terminals 4 of the LM224 operational amplifier. The ground terminal 11 of the LM224 operational amplifier 65 is electrically coupled to the common ground 61. A reference voltage is supplied to each operational amplifier 65 from the OUT terminal of the voltage regulator circuit (designated O) 62. For the first voltage comparator circuit 63, the negative terminal designated 2 of the operational amplifier 65 is connected to the voltage regulator 62 via a series resistor R4, which is generally a 1%, 1 kilo-ohm resistor; and the positive terminal 5 of the operational amplifier 65 is connected to the voltage regulator 62 via a series resistor R5, which is generally a 1%, 1 kilo-ohm resistor. Likewise, for the second voltage comparator circuit 64, the negative terminal designated 9 of the operational amplifier 65 is connected to the voltage regulator 62 via a series resistor R11, which is generally a 1%, 1 kilo-ohm resistor; and the positive terminal 12 of the operational amplifier 65 is connected to the voltage regulator 62 via a series resistor R12, which is generally a 1%, 1 kilo-ohm resistor.

The input voltage to be monitored by each of the voltage comparator circuits 63 and 64 is provided by the first and second battery sources, 21 and 22 respectively, via a voltage divider circuit 66 to the LM224 operational amplifier 65. With respect to the voltage divider circuit 66, and for the first voltage comparator circuit 63, the first or main battery source 21 is electrically connected to the positive input terminal 3 of the operational amplifier 65 via a series resistor R1, and which is generally sized at 3.3 kilo-ohms, and is further electrically shunted by a parallel resistor R2, which is a 1%, 6.81 kilo-ohm resistor. Further, the positive input terminal 3 is electrically shunted to the common ground 61 by a resistor R5, which is generally sized at 47 kilo-ohms, and a capacitor C5, generally sized at 0.01 microfarads, in series. The negative input 6 of the operational amplifier 65 is electrically coupled to the positive input terminal 3 via a resistor R3, which is a 1%, 1 kilo-ohm resistor. The voltage divider circuit 66 is protected by a reverse-biased diode D1 which is placed in parallel with a capacitor C3, which is generally sized at 220 microfarads. The diode D1 is a 1N4007 rectifier, which is generally commercially available from a number of electronics suppliers. Likewise, for the second voltage comparator circuit 64, the second or auxiliary battery source 22 is electrically connected to the positive input terminal 10 of the operational amplifier 65 via a series resistor R8, which is generally sized at 3.3 kilo-ohms, and is further electrically shunted by a parallel resistor R9, which is a 1%, 6.81 kilo-ohm resistor. The positive input terminal 10 is then shunted to the common ground 61 by a resistor R13, generally sized at 47 kilo-ohms and a capacitor C6, which is generally sized at 0.01 microfarads. The resistor R13 and the capacitor C6 are in series. The negative input 13 of the differential amplifier 65 is tied to the positive input terminal 10 via a resistor R10, which is a 1%, 1 kilo-ohm resistor. The voltage divider circuit 66 is protected by a reverse-biased diode D2 which is placed in parallel with a capacitor C4, and which is generally sized at 220 microfarads. The diode D2 is a 1N4007 rectifier, which is generally available from a number of electronics suppliers.

As discussed earlier, the outputs 1, 7, 8 and 14 of the operational amplifier 65 operate the charge status lights 44 and 45 as well as the audio alarm 41. Referring still to FIG. 3, with respect to the first comparator circuit 63, the output terminal 1 of the operational amplifier 65, if energized, will forward bias the green light emitting diode of diode D5, through series resistor R7, which is generally sized at 47 kilo-ohms, to the common ground 61. In this case, the light emitting diode D5, which is the charge status light 44 for the first or main batteries, will emit a green light, indicating an acceptable voltage level. If the output terminal 7 of the operational amplifier 65 is energized, it will forward bias the red light emitting diode of diode D5, through series resistor R7 to the common ground 61. In this case, the charge status light 44 will emit a red light, indicating an unacceptable predetermined reference voltage level. In the arrangement as seen in the drawings, this occurs when the battery voltage reaches 11.5 volts. Further, the output terminal 7 of the operational amplifier 65 is connected through a series resistor R15, generally sized at 1 kilo-ohm, and Diode D3 (an IN4007 rectifier) to operate an electronic switch Q1, which in turn energizes the audio alarm 41, which may be an electric buzzer or other electrically operated sound generator. The electronic switch Q1, as shown in FIG. 3, may be a BS170 field effect transistor, commonly available from a number of integrated circuit manufacturers. The audio alarm 41 is powered by an electrical connection to the first or main battery source 21 through a alarm cut-off switch 42. Therefore, if the alarm cut-off switch is in the “ON” position, the electronic switch Q1 will complete a circuit from the first battery source 21 to the audio alarm 41 and then to the common ground 61, thus activating the audio alarm 41. Likewise, with respect to the second comparator circuit 64, the output terminal 8 of the operational amplifier 65, if energized, will forward bias the green light emitting diode of diode D6, through series resistor R14, which is generally sized at 47 kilo-ohms, to the common ground 61. In this case, the light emitting diode D6, which is the charge status light 45 for the second or auxiliary batteries, will emit a green light, indicating an acceptable voltage level. If the output terminal 14 of the operational amplifier 65 is energized, it will forward bias the red light emitting diode of diode D6, through series resistor R14 to the common ground 61. In this case, the charge status light 45 will emit a red light, indicating an unacceptable predetermined reference voltage level. Again, this typically occurs when the battery voltage reaches 11.5 volts DC. Further, the output terminal 14 of the operational amplifier 65 is connected through a series resistor R16, generally sized at 1 kilo-ohm, and Diode D4 (an IN4007 rectifier) to operate the electronic switch Q1, which in turn energizes the audio alarm 41, as discussed above. in another possible form of the invention, similar circuitry can be employed to provide a visual and audio warning if the batteries being monitored have achieved an overly charged status. In this case, the circuitry provides a predetermined overvoltage setting. Those skilled in the art will recognize that over charging a battery may cause a potentially dangerous situation to develop which may result in the destruction of the battery and damage to the watercraft 11. This could occur when the charging system (not shown) of the watercraft 11 malfunctions during operation or where the charge control circuitry of an auxiliary charging system, like those employed dockside in some marinas or charging systems employing solar panels or wind generated power systems, malfunctions.

### OPERATION

The operation of the described embodiment of the present invention is believed to be readily apparent and is briefly summarized at this point.

Referring now to FIG. 3, a first aspect of the present invention relates to a battery monitor 10 for marine applications, and which includes a first voltage comparator circuit 63 which compares a voltage input V1 of a marine battery 21 to a first predetermined reference voltage; and an audible alarm 41 is provided which operates when the voltage comparator circuit 63 determines that the voltage input V1 of the marine battery 21 is below that of the first predetermined reference voltage V1. In the arrangement as seen in the drawings, the battery monitor 10 draws less than 100 milliamps of current on a continuous basis while monitoring the voltage input V1 of the marine battery 21. In the arrangement as seen in FIG. 3, a second voltage comparator circuit 64 compares the voltage input of the marine battery 21 to a second predetermined reference voltage, and which operates the audible alarm 41 when the second voltage comparator circuit determines that the voltage input of the marine battery is above that of the second predetermined reference voltage. In the arrangement as seen in FIG. 1, the battery monitor 10 includes, among other features, a numerical display 40 which displays the voltage input of the marine battery 21. Additionally, the battery monitor 10 includes an alarm switch 42 which allows a user 15 to enable or disable the audible alarm 41. As seen earlier in the drawings, the battery monitor 10 includes a substantially moisture resistant housing 30 enclosing the first voltage comparator circuit 63. Moreover, it should be understood that the moisture resistant housing occupies a surface area of less than about 9.5 square inches. In the arrangement as seen in the drawings, the audible alarm 41 has an audible volume which will allow an operator of a marine craft 11 to hear the audible alarm when the marine craft is in operation. Additionally, the battery monitor 10 includes a visible status light 44 or 45 which will become energized when the marine battery 21 or 22 which is being monitored is below a predetermined reference voltage. In the arrangement as seen in FIG. 2, the battery monitor 10 for marine applications is further rendered operable to monitor a second marine battery 22. Still further, the display switch 43 is provided which permits an operator 15 to display a voltage condition of either the first marine battery 21 or the second marine battery 22 by means of the numerical display 40. Additionally, in this form of the invention, a second visible status light 45 is provided and which will become energized and change color when the second marine battery 22 is below a predetermined reference voltage.

A second aspect of the present invention relates to a battery monitor 10 for marine applications which-includes a voltage input V1 which receives a voltage from a marine battery 21 and a first voltage comparator circuit 63 which compares the voltage input V1 of the marine battery 21 to a predetermined reference undervoltage setting. In this form of the invention, the battery monitor 10 further includes a second voltage comparator circuit 64 which compares the voltage input of the marine battery 21 to a predetermined reference overvoltage setting. In the arrangement as seen in the drawings, an audible alarm 41 is provided which operates when either the first voltage comparator circuit 63 determines that the voltage input V1 is below the predetermined reference undervoltage setting, or when the second voltage comparator circuit 64 determines that the voltage input is above the predetermined reference overvoltage setting; and a numerical display 40 is provided and which displays the value of the voltage input V1 of the marine battery 21 which is being monitored. In the arrangement as described in the present invention, the battery monitor includes an alarm switch 42 which allows a user 15 to select between enabling or disabling the audible alarm 41. Additionally, in this form of the invention, the battery may comprise a second battery 22 connected in parallel or in series with a first battery 21. Further, it will be recognized that in this form of the invention, the battery monitor 10 and more specifically, the second battery 22 thereof, may comprise a plurality of batteries which are coupled together in series parallel or a combination of series and parallel connections. In the battery monitor 10 as seen in FIG. 3, the first voltage comparator circuit 63 comprises, at least in part, a voltage divider circuit 66 and further includes an operational amplifier 65. The voltage divider circuit 66 comprises at least two resistors R1 and R2 which are sized so as to set the predetermined reference undervoltage setting. Further, the operational amplifier 65 delivers an operational voltage to the audible alarm 41 when the input voltage V1 is below the predetermined reference undervoltage setting. Further, the battery monitor as described above, includes a second voltage comparator circuit 64 which includes a voltage divider circuit 66, and an operational amplifier 65. In this arrangement, the voltage divider circuit 66 comprises at least two electrical resistors R8 and R9, respectively, and which are sized so as to set the predetermined reference overvoltage setting. The operational amplifier 65 delivers an operational voltage to the audible alarm 41 when the input voltage V1 is above the predetermined reference overvoltage setting.

A further aspect of the present invention relates to a battery monitor 10 for marine applications which includes a first voltage input V1 which receives a voltage from a first battery 21; and a second voltage input V2 which receives a voltage from a second battery 22. In this arrangement, a first voltage comparator circuit 63 compares the first and second voltage inputs V1 and V2 to a predetermined reference undervoltage setting. Further, a second voltage comparator circuit 64 compares the first and second voltage inputs V1 and V2 to a predetermined reference overvoltage setting. In the arrangement as seen, an audible alarm 41 operates when either the first voltage comparator circuit 63 determines that either the first or second voltage inputs V1 or V2 are below the predetermined reference undervoltage setting, or when the second voltage comparator circuit 64 determines that either the first or second voltage inputs V1 and V2 is above the predetermined reference overvoltage setting. Further, a battery display selector switch 43 is provided and which selects either the first or second voltage input values V1 or V2 to be displayed upon a numerical display.

Therefore, it will be seen that the present battery monitor for marine applications provides many advantages over prior art devices which have been employed for substantially similar purposes heretofore and substantially prevents operators of watercraft from becoming stranded in remote locations as a result of dangerous electrical discharges of the batteries which support the operation of the watercraft.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

I claim:

1. A battery monitor for marine applications, comprising:
a first voltage comparator circuit which compares a voltage input of a marine battery to a first predetermined reference voltage; and
an audible alarm which operates when the voltage comparator circuit determines that the voltage input of the marine battery is below that of the first predetermined reference voltage, and wherein the battery monitor draws less than 100 milliamps of current on a continuous basis while monitoring the voltage input of the marine battery.

2. A battery monitor for marine applications as claimed in claim 1, and further comprising a second voltage comparator circuit which compares the voltage input of the marine battery to a second predetermined reference voltage, and which operates the audible alarm when the second voltage comparator circuit determines that the voltage input of the marine battery is above that of the second predetermined reference voltage.

3. A battery monitor for marine applications as claimed in claim 1, and further comprising a numerical display which displays the voltage input of the marine battery.

4. A battery monitor for marine applications as claimed in claim 1, and further comprising an alarm switch which allows a user to enable or disable the audible alarm.

5. A battery monitor for marine applications as claimed in claim 1, and further comprising a substantially moisture resistant housing for enclosing the first voltage comparator circuit.

6. A battery monitor for marine applications as claimed in claim 5, and wherein the moisture resistant housing occupies a surface area of less than about 9.5 square inches.

7. A battery monitor for marine applications as claimed in claim 1, and wherein the audible alarm has an audible volume which will allow an operator of a marine craft to hear the audible alarm when the marine craft is in operation.

8. A battery monitor for marine applications as claimed in claim 1, and further comprising a visible status light which will become energized when the marine battery is below the predetermined reference voltage.

9. A battery monitor for marine applications as claimed in claim 3, and further comprising:
a second marine battery; and
a display switch which permits an operator to display a voltage condition of either the first marine battery or the second marine battery by means of the numerical display.

10. A battery monitor for marine applications as claimed in claim 9, and further comprising a second visible status light which will become energized and change color when the second marine battery is below a predetermined reference voltage.

11. A battery monitor for marine applications, comprising:
a voltage input which receives a voltage from a marine battery;
a first voltage comparator circuit which compares the voltage input of the marine battery to a predetermined reference undervoltage setting;
a second voltage comparator circuit which compares the voltage input of the marine battery to a predetermined reference overvoltage setting;
an audible alarm which operates when either the first voltage comparator circuit determines that the voltage input is below the predetermined reference undervoltage setting, or when the second voltage comparator circuit determines that the voltage input is above the predetermined reference overvoltage setting; and
a numerical display which displays the value of the voltage input of the marine battery.

12. A battery monitor for marine applications as claimed in claim 11, and further comprising an alarm switch which allows a user to select between enabling or disabling the audible alarm.

13. A battery monitor for marine applications as claimed in claim 11, and wherein the battery comprises a second battery connected in parallel or in series with a first battery.

14. A battery monitor for marine applications as claimed in claim 13, and wherein the second battery comprises a plurality of batteries which are coupled together in series, parallel, or a combination of series and parallel connection.

15. A battery monitor for marine applications as claimed in claim 11, and wherein the battery monitor draws less than about 100 milliamps on a continuous basis when monitoring the battery.

16. A battery monitor for marine applications as claimed in claim 11, and wherein the first voltage comparator circuit comprises a voltage divider circuit, and an operational amplifier, and wherein the voltage divider circuit comprises at least two electrical resistors sized so as to set the predetermined reference undervoltage setting, and wherein the operational amplifier delivers an operational voltage to the audible alarm when the input voltage is below the predetermined reference undervoltage setting.

17. A battery monitor for marine applications as claimed in claim 11, and wherein the second voltage comparator circuit comprises a voltage divider circuit, and an operational amplifier, and wherein the voltage divider circuit comprises at least two electrical resistors sized so as to set the predetermined reference overvoltage setting, and wherein the operational amplifier delivers an operational voltage to the audible alarm when the input voltage is above the predetermined reference overvoltage setting.

18. A battery monitor for marine applications, comprising:
a first voltage input which receives a voltage from a first battery;
a second voltage input which receives a voltage from a second battery;
a first voltage comparator circuit which compares the first and second voltage input to a predetermined reference undervoltage setting;
a second voltage comparator circuit which compares the first and second voltage input to a predetermined reference overvoltage setting;
an audible alarm which operates when either the first voltage comparator circuit determines that either the first or second voltage input is below the predetermined reference undervoltage setting, or when the second voltage comparator circuit determines that either the first or second voltage inputs is above the predetermined reference overvoltage setting; and
a battery display selector switch which selects either the first or second voltage input value to be displayed upon a numerical display.

19. A battery monitor for marine applications as claimed in claim 18, and further comprising an alarm switch which allows a user to enable or disable the audible alarm.

20. A battery monitor for marine applications as claimed in claim 19, and wherein the audible alarm has an audible volume which will allow an operator of a marine craft to hear the audible alarm when the marine craft is in operation.
